(19) United States
(12) Patent Application Publication
(10) Pub. No.: US 2025/0343393 A1
(43) Pub. Date: Nov. 6, 2025

(54) OPTICAL SEMICONDUCTOR DEVICE

(71) Applicant: FURUKAWA ELECTRIC CO., LTD., Tokyo (JP)

(72) Inventors: Kazuaki KIYOTA, Tokyo (JP); Kenshiro MATSUSHIMA, Tokyo (JP)

(73) Assignee: FURUKAWA ELECTRIC CO., LTD., Tokyo (JP)

(21) Appl. No.: 19/267,074

(22) Filed: Jul. 11, 2025

Related U.S. Application Data
(63) Continuation of application No. PCT/JP2024/003307, filed on Feb. 1, 2024.

(30) Foreign Application Priority Data
Feb. 1, 2023 (JP) 2023-013793

(51) Int. Cl. H01S 5/22; H01S 5/227; H01S 5/343

(52) U.S. Cl. CPC H01S 5/2205; H01S 5/227; H01S 5/3434

(57) ABSTRACT

An optical semiconductor device includes: an n-type cladding layer; a p-type cladding layer; and an active layer interposed between the n-type cladding layer and the p-type cladding layer. The n-type cladding layer includes a base layer, and an electric field distribution adjusting structure configured by alternately and periodically layering multiple first layers and multiple second layers, the multiple first layers having same refractive index as the base layer, the multiple second layers having a higher refractive index than a refractive index of the first layers. The multiple second layers include a relaxation layer located at a position near at least one end from a center in a layering direction of the first layers and the second layers of the electric field distribution adjusting structure, the relaxation layer having a smaller thickness than a thickness of the other second layers.

This application is a continuation of International Application No. PCT/JP2024/003307, filed on Feb. 1, 2024 which claims the benefit of priority of the prior Japanese Patent Application No. 2023-013793, filed on Feb. 1, 2023, the entire contents of which are incorporated herein by reference.

### BACKGROUND

The present disclosure relates to an optical semiconductor device.

In optical semiconductor devices having an active layer, such as a semiconductor laser element or a semiconductor optical amplifier, a technique has been disclosed in which a layer having a high refractive index is provided in an n-type cladding layer to bias an electric field distribution of laser light propagating through the active layer toward the n-type cladding layer. This technique may reduce an inter-valence band optical absorption in a p-type cladding layer, improve a kink level, and adjust a far-field pattern in a vertical direction (JP 2000-174394 A, JP 2001-210910 A, JP 3525257 B2, JP 2004-356608 A, JP 2013-120893 A, and WO 2013/151145 A). Such a layer having a high refractive index is also called an electric field distribution adjusting layer.

For such an electric field distribution adjusting layer, a layered structure in which multiple layers are layered alternately and periodically with layers having a low refractive index is suitable rather than a single layer structure having a large layer thickness, since this configuration may achieve crystal growth with fewer defects.

### SUMMARY

In a manufacturing process of optical semiconductor devices, an intermediate inspection process for characteristics of an active layer of the optical semiconductor device may emit light by irradiating the active layer from an opposite side of a substrate, measure an emission spectrum of light, and inspect characteristics of the active layer according to a peak wavelength of the emission spectrum.

However, according to a study by the present inventor, characteristics of an active layer obtained from the emission spectrum in the intermediate inspection may differ from characteristics of an active layer in a finished product, in the optical semiconductor device having the electric field distribution adjusting layer as described above. Such a difference may cause a misjudgment of the active layer characteristics in the intermediate inspection, and thus may lead to a decrease in yield and an increase in manufacturing cost of the optical semiconductor device.

There is a need for an optical semiconductor device in which a decrease in manufacturing yield and an increase in manufacturing cost are reduced.

According to one aspect of the present disclosure, there is provided an optical semiconductor device including: an n-type cladding layer; a p-type cladding layer; and an active layer interposed between the n-type cladding layer and the p-type cladding layer, wherein the n-type cladding layer includes a base layer, and an electric field distribution adjusting structure configured by alternately and periodically layering multiple first layers and multiple second layers, the multiple first layers having same refractive index as the base layer, the multiple second layers having a higher refractive index than a refractive index of the first layers, and the multiple second layers include a relaxation layer located at a position near at least one end from a center in a layering direction of the first layers and the second layers of the electric field distribution adjusting structure, the relaxation layer having a smaller thickness than a thickness of the other second layers.

According to another aspect of the present disclosure, there is provided an optical semiconductor device including: an n-type cladding layer; a p-type cladding layer; and an active layer interposed between the n-type cladding layer and the p-type cladding layer, wherein the n-type cladding layer includes a base layer, and an electric field distribution adjusting structure configured by alternately and periodically layering multiple first layers and multiple second layers, the multiple first layers having same refractive index as the base layer, the multiple second layers having a higher refractive index than a refractive index of the first layers, the multiple second layers include a first relaxation layer located at a position near a first end from a center in a layering direction of the first layers and the second layers of the electric field distribution adjusting structure, and a second relaxation layer located at a position near a second end from the center, and the first relaxation layer and the second relaxation layer have a lower refractive index than a refractive index of the other second layers.

### BRIEF DESCRIPTION OF THE DRAWINGS

FIG. 1 is a schematic cross-sectional view of an optical semiconductor device according to a first embodiment;

FIG. 2 is a diagram illustrating a relationship between a layered structure of semiconductor layers and a refractive index in FIG. 1;

FIG. 3A is a schematic view illustrating a state in which ripples are reduced;

FIG. 3B is a schematic view illustrating a state in which ripples are reduced;

FIG. 4 is a diagram illustrating a relationship between the layered structure of the semiconductor layers and the refractive index in the optical semiconductor device according to a second embodiment; and

FIG. 5 is a diagram illustrating a relationship between the layered structure of the semiconductor layers and the refractive index in the optical semiconductor device according a third embodiment.

### DETAILED DESCRIPTION

Hereinafter, embodiments will be described with reference to drawings. Note that the present disclosure is not limited by the embodiments. In addition, in the description of the drawings, the same or corresponding elements are appropriately denoted by the same reference numerals, and redundant descriptions are appropriately omitted. In addition, it should be noted that the drawings are schematic, and a dimensional relationship of each element, a ratio of each element, and the like may be different from reality. Portions having different dimensional relationship and ratio may also be included between the drawings.

The present inventor investigated a cause of a difference between characteristics of an active layer obtained in an intermediate inspection and characteristics of an active layer in a finished product, and has confirmed that an emission spectrum obtained in the intermediate inspection has a superimposed reflected light component due to an electric field distribution adjusting layer. The present inventor has then confirmed that the emission spectrum, particularly a peak wavelength may not be accurately measured, since a wavelength spectrum of reflected light is not flat in intensity and includes ripples. As such, the present inventor has conceived that the ripples in the wavelength spectrum of reflected light are reduced by providing a relaxation layer in a structure including the electric field distribution adjusting layer, and has completed the present disclosure.

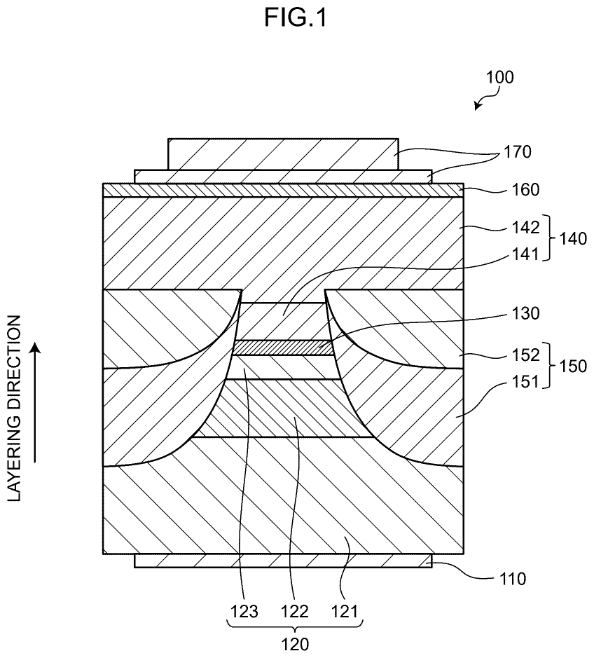

FIG. 1 is a schematic cross-sectional view of the optical semiconductor device according to a first embodiment. The optical semiconductor device 100 is configured as a semiconductor laser element. The optical semiconductor device 100 comprises an n-type cladding layer 120 in which an n-side electrode 110 is formed on a back surface, an active layer 130, a p-type cladding layer 140, a current blocking layer 150, a contact layer 160, and a p-side electrode 170. The optical semiconductor device 100 outputs laser light from the active layer 130 in a direction vertical to a paper surface. A wavelength of laser light is, for example, in a 1.55 μm band. A semiconductor material for adjusting the wavelength of laser light to a wavelength in the 1.55 μm band, which may be an indium phosphide (InP)-based material is known.

The n-type cladding layer 120 is a semiconductor layer having an n-type conductivity. The p-type cladding layer 140 is a semiconductor layer having a p-type conductivity. The active layer 130 is interposed between the n-type cladding layer 120 and the p-type cladding layer 140.

The n-type cladding layer 120 includes base layers 121 and 123, and an electric field distribution adjusting structure 122 interposed between the base layers 121 and 123.

The base layer 121 has a structure in which a buffer layer made of n-type InP (Hereinafter, appropriately described as an n-InP) is layered on a substrate made of n-InP by e.g. epitaxial growth. The base layer 123 is made of n-InP. The electric field distribution adjusting structure 122 will be described in detail later.

The n-type semiconductor layer herein includes, for example, but not particularly limited to, silicon (Si), sulfur(S), and selenium (Se) as n-type impurities.

The active layer 130 has an MQW-SCH structure made of an MOW layer having a multi quantum well (MQW) structure made of multiple barrier layers and multiple well layers, as well as two separate confinement heterostructure (SCH) layers arranged so as to sandwich the MQW layer. The active layer 130 is made of, for example, n-type GaInAsP which is an InP-based quaternary semiconductor material. A composition ratio of the semiconductor material constituting the well layers of the active layer 130 is set so as to emit light at a desired laser emission wavelength

Ac. A composition ratio of the semiconductor material constituting the barrier layers and the SCH layers is set so as to satisfy each function. The active layer 130 may have a single quantum well structure.

The p-type cladding layer 140 has a layered structure of semiconductor layers 141 and 142 made of a p-type InP (Hereinafter, appropriately described as a p-InP).

The p-type semiconductor layer herein includes, for example, but not particularly limited to, zinc (Zn) as p-type impurities.

A part of the n-type cladding layer 120, the active layer 130, and a part of the p-type cladding layer 140 have a stripe mesa structure. The stripe mesa structure, for example, is etched or fabricated to a width that is suitable for guiding light in a 1.55 μm band in a single mode (e.g. 2 μm). Both sides of the stripe mesa structure (left and right directions in the drawing) are embedded by the current blocking layer 150, which is configured by layering a current blocking layer 151 made of p-InP and a current blocking layer 152 made of n-InP. The semiconductor layer 142 is formed so as to cover the semiconductor layer 141 and the current blocking layer 150.

The contact layer 160, for example, is made of p-type GaInAsP and is in ohmic contact with the p-side electrode 170. The p-side electrode 170 includes, for example, titanium, platinum, gold, or the like.

The n-side electrode 110 is provided so as to be in ohmic contact with the substrate of the n-type cladding layer 120. The n-side electrode 110 includes, for example, gold, nickel, or the like.

Both end facets of the optical semiconductor device 100 that are parallel to the drawing are formed by cleaving. A High Reflection (HR) film having a relatively high reflectivity is formed on one end facet, and an Anti-Reflection (AR) film for preventing reflection is formed on the other end facet. The HR film and the AR film form a laser resonator. The optical semiconductor device 100 outputs laser light mainly from the end facet on which the AR film is formed.

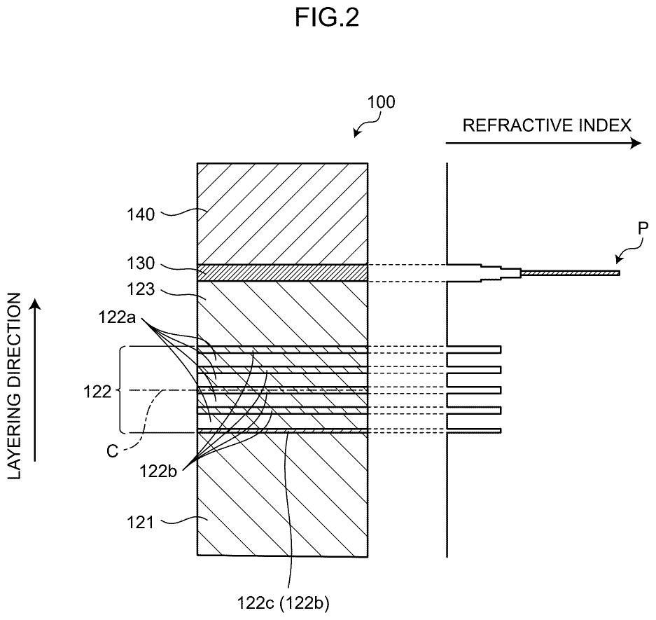

FIG. 2 is a diagram illustrating a relationship between the layered structure of the semiconductor layer in FIG. 1 and the refractive indices. FIG. 2 illustrates the refractive indices of the base layers 121 and 123, the electric field distribution adjusting structure 122, the active layer 130, and the p-type cladding layer 140. Any of the base layers 121 and 123 and the p-type cladding layer 140 are made of InP, and thus have the same refractive index. In addition, the active layer 130 is made of n-GaInAsP, and has a higher refractive index than that of the base layers 121 and 123 and the p-type cladding layer 140. Note that a region P in the refractive index of the active layer 130 illustrates a refractive index of a portion where the well layers and the barrier layers are alternately layered, and this region P alternately includes portions having a high refractive index and a portion having a relatively low refractive index.

Next, the configuration and the refractive indices of the electric field distribution adjusting structure 122 will be specifically described with reference to FIG. 2. The electric field distribution adjusting structure 122 has multiple first layers 122a and multiple second layers 122b. The electric field distribution adjusting structure 122 is configured with the first layers 122a and the second layers 122b alternately and periodically layered. Although five second layers 122b are illustrated in FIG. 2, the number of second layers 122b is not limited to five.

The first layers 122a are made of semiconductors having the same refractive index as the base layers 121 and 123. For example, the first layers 122a are made of n-InP. In addition, all the first layers 122a have the same layer thickness. The layer thickness of the first layers 122a is, for example, but not limited to, 120 nm.

The second layers 122b have a higher refractive index than that of the first layers 122a. In addition, all the second layers 122b have the same refractive index. That is, the second layers 122b have a higher refractive index than that of the base layers 121 and 123. For example, the second layers 122b are made of n-GaInAsP, and those compositions are adjusted so as to have a desired refractive index. For example, the composition of the GaInAsP is adjusted so that its composition wavelength is 1.2 μm. Here, the composition wavelength means a light wavelength corresponding to a band gap energy of a semiconductor material. Thus, changing the composition of the semiconductor layer also changes its refractive index, its band gap energy, and its composition wavelength.

Note that the GaInAsP is an example of a group III-V compound semiconductor including As and P as a composition. The second layers 122b are also called an electric field distribution adjusting layer.

Here, multiple second layers 122b include a relaxation layer 122c. The relaxation layer 122c is located at a position near one end from a center C in a layering direction of the first layers 122a and the second layers 122b, specifically at an end on the side far from the active layer 130 of the electric field distribution adjusting structure 122. The relaxation layer 122c has a smaller layer thickness than that of the other second layers 122b. For example, the layer thickness of the other second layers 122b are 20 nm, and the layer thickness of the relaxation layer 122c is 10 nm. As such, the layer thickness of the relaxation layer 122c is smaller than that of the other second layers 122b, an equivalent refractive index of the relaxation layer 122c is thus also smaller than that of the other second layers 122b. Specifically, the equivalent refractive index of the relaxation layer 122c is closer to that of the first layers 122a made of n-InP than to that of the other second layers 122b.

If all the multiple second layers 122b, including the relaxation layer 122c, have the same layer thickness and the same refractive index, a reflection spectrum with ripples is superimposed on an emission spectrum when measuring the emission spectrum of the active layer 130, as described above. Therefore, an original emission spectrum of the active layer 130 cannot be measured, making it difficult to accurately know the characteristics of the active layer 130.

On the other hand, the optical semiconductor device 100 according to the first embodiment has the relaxation layer 122c with a smaller layer thickness than that of the other second layers 122b in the electric field distribution adjusting structure 122, and thus reduces ripples of the reflection spectrum. As a result, the optical semiconductor device 100 allows to perform more accurate intermediate inspection, reducing a decrease in manufacturing yield and an increase in manufacturing cost.

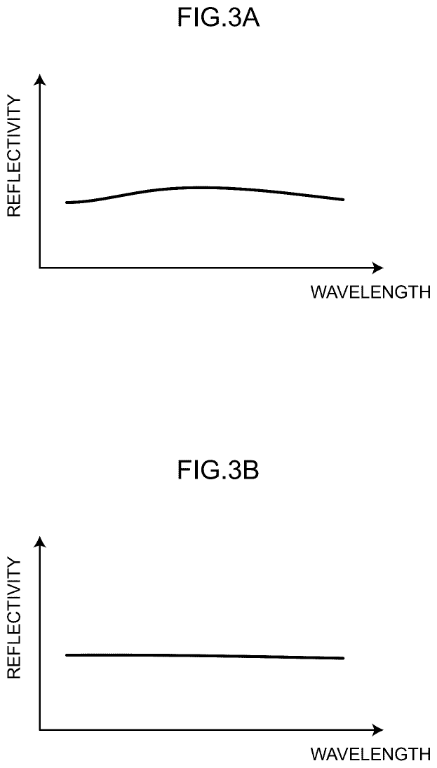

FIGS. 3A and 3B are schematic diagrams illustrating a state in which ripples are reduced in a reflectivity spectrum. The illustrated wavelength range is an emission wavelength band of the active layer 130. FIG. 3A illustrates a case where all the multiple second layers 122b, including the relaxation layer 122c, have the same layer thickness and the same refractive index. In this case, ripples are generated in the reflectivity spectrum. On the other hand, FIG. 3B illustrates a case where the electric field distribution adjusting structure 122 include the relaxation layer 122c with a smaller layer thickness than that of the other second layers 122b. As can be seen from FIG. 3B, in this case, the reflectivity spectrum has reduced ripples and is flatter as compared with the spectrum of FIG. 3A.

In addition, in the optical semiconductor device 100, the layer thickness of the relaxation layer 122c is adjusted so that the relaxation layer 122c has a smaller equivalent refractive index than that of the other second layers 122b. The optical semiconductor device 100 thus facilitates adjustment of the equivalent refractive index in a crystal growth process, thereby facilitating a reduction of ripples.

In addition, the optical semiconductor device 100 has the electric field distribution adjusting structure 122, and thus may reduce an inter-valence band optical absorption in the p-type cladding layer 140, improve a kink level, and adjust a far-field pattern in a vertical direction.

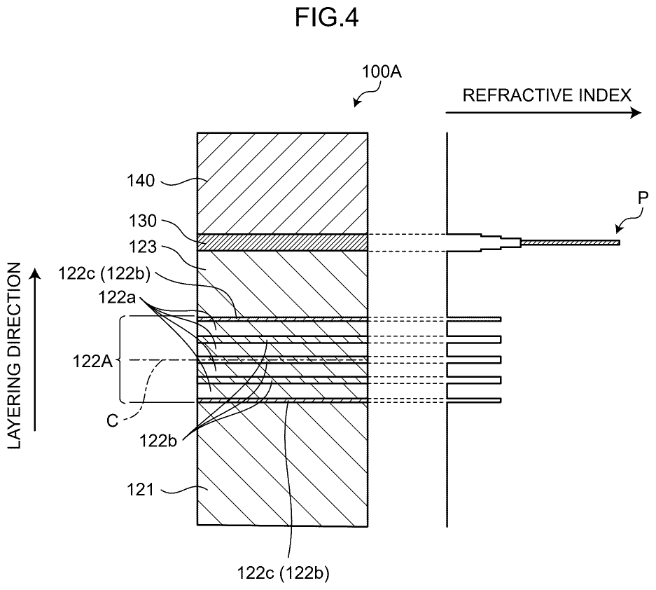

Next, an optical semiconductor device according to a second embodiment will be described. FIG. 4 is a diagram illustrating a relationship between a layered structure of semiconductor layers and refractive indices in an optical semiconductor device 100A according to the second embodiment. The optical semiconductor device 100A has a configuration in which the electric field distribution adjusting structure 122 in the configuration of the optical semiconductor device 100 according to the first embodiment is replaced with an electric field distribution adjusting structure 122A. Accordingly, the electric field distribution adjusting structure 122A will be mainly described below.

As illustrated in FIG. 4, the electric field distribution adjusting structure 122A has a configuration in which a second layer 122b located at the end on the side near the active layer 130 in the configuration of the electric field distribution adjusting structure 122 is replaced with a relaxation layer 122c. The relaxation layer 122c has the same layer thickness and the same refractive index as the relaxation layer 122c located at the end on the side far from the active layer 130 of the electric field distribution adjusting structure 122A.

The relaxation layer 122c located at the end on the side near the active layer 130 of the electric field distribution adjusting structure 122A is an example of a second relaxation layer which is the relaxation layer located at a position near the second end from the center C of the electric field distribution adjusting structure 122A. In addition, the relaxation layer 122c located at the end on the side far from the active layer 130 of the electric field distribution adjusting structure 122A is an example of a first relaxation layer which is the relaxation layer located at a position near the first end from the center C.

Similarly to the optical semiconductor device 100, the optical semiconductor device 100A may reduce an inter-valence band optical absorption in the p-type cladding layer 140, improve a kink level, and adjust a far-field pattern in a vertical direction. Furthermore, the optical semiconductor device 100A is provided with two relaxation layers 122c at the end on the side far from the active layer 130 and the end on the side near the active layer 130, and thus further reduces ripples of the reflection spectrum. As a result, the optical semiconductor device 100A further reduces a decrease in manufacturing yield and an increase in manufacturing cost.

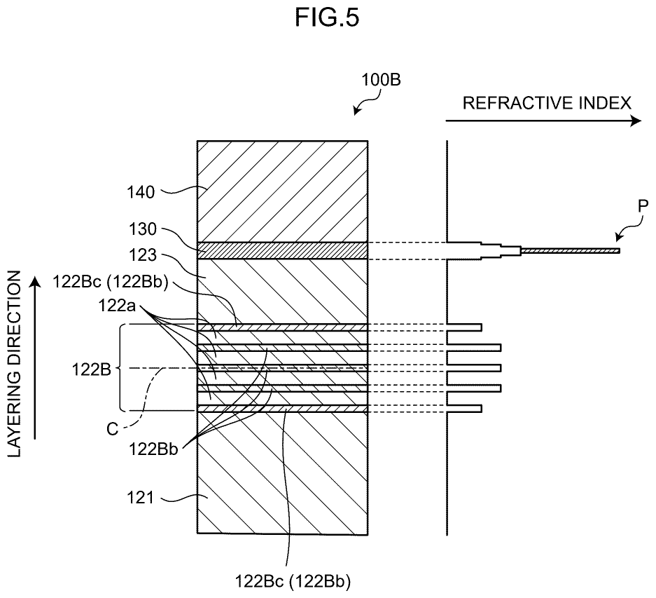

Next, an optical semiconductor device according to a third embodiment will be described. FIG. 5 is a diagram illustrating a relationship between a layered structure of semiconductor layers and refractive indices in an optical semiconductor device 100B according to the third embodiment. The optical semiconductor device 100B has a configuration in which the electric field distribution adjusting structure 122A in the configuration of the optical semiconductor device 100A according to the second embodiment is replaced with an electric field distribution adjusting structure 122B. Accordingly, the electric field distribution adjusting structure 122B will be mainly described below.

As illustrated in FIG. 5, the electric field distribution adjusting structure 122B has a configuration in which the second layers 122b in the configuration of the electric field distribution adjusting structure 122A is replaced with second layers 122Bb, as well as the relaxation layer 122c is replaced with a relaxation layer 122Bc.

That is, the electric field distribution adjusting structure 122B includes multiple first layers 122a and multiple second layers 122Bb. The electric field distribution adjusting structure 122B is configured with the first layers 122a and the second layers 122Bb alternately and periodically layered. Although five second layers 122Bb are illustrated in FIG. 5, the number of the second layers 122Bb is not limited to five.

The second layers 122Bb have a higher refractive index than that of the first layers 122a. For example, the second layers 122Bb is made of n-type GaInAsP, and its composition is adjusted so as to have a desired refractive index. In addition, all the second layers 122Bb have the same layer thickness.

The multiple second layers 122Bb include two relaxation layers 122Bc. The two relaxation layers 122Bc are respectively located at a position near ends from the center C in a layering direction of the first layers 122a and the second layers 122Bb, specifically at an end near to or far from the active layer 130 in the electric field distribution adjusting structure 122B. The relaxation layer 122Bc located at the end on the side far from the active layer 130 is an example of a first relaxation layer located at a position near to a first end from the center C, and the relaxation layer 122Bc located at the end on the side near to the active layer 130 is an example of a second relaxation layer located at a position near a second end from the center C.

Here, the relaxation layers 122Bc have a lower refractive index than that of the other second layers 122Bb. For example, in the other second layers 122Bb, a composition of GaInAsP is adjusted so that its composition wavelength is 1.2 μm On the other hand, in the relaxation layers 122Bc, a composition of GaInAsP is adjusted so that its composition wavelength is 1.05 μm which is shorter than 1.2 μm, and its refractive index decreases accordingly. As such, the relaxation layers 122Bc have a lower refractive index than that of the other second layers 122Bb, and thus have a lower equivalent refractive index than that of the other second layers 122Bb as well.

The optical semiconductor device 100B configured as such has the relaxation layers 122Bc with the lower refractive index than that of other second layers 122Bb in the electric field distribution adjusting structure 122B, and thus reduces ripples in the reflection spectrum. As a result, optical semiconductor device 100B allows to perform more accurate intermediate inspection, reducing a decrease in manufacturing yield and an increase in manufacturing cost.

In addition, attempting to make a difference in an equivalent refractive index between the relaxation layers 122Bc and the other second layers 122Bb by adjusting their composition sometimes fail to make a sufficient difference. In such cases, the effect of reducing reflection ripples cannot be fully achieved. On the other hand, the optical semiconductor device 100B is provided with two relaxation layers 122Bc, and thus adds an effect of reducing the reflection ripples by each relaxation layer 122Bc, thereby achieving a sufficient effect.

Further, in the optical semiconductor device 100B, similarly to the optical semiconductor device 100A, may reduce an inter-valence band optical absorption in the p-type cladding layer 140, improve a kink level, and adjust a far-field pattern in a vertical direction.

Although the refractive index of the relaxation layers 122c is equal to that of the other second layers 122b in the first and second embodiments, the refractive index of the relaxation layers 122c may be lower than that of the other second layers 122b. As a result, the effect of reducing the reflection ripples may be further achieved.

Although the relaxation layer(s) is/are located at an end position(s) in the layering direction of the electric field distribution adjusting structure in the first to third embodiments, the position(s) of the relaxation layer(s) is/are not limited to the position(s). The relaxation layer is effective when being located at a position near an end from the center in the layering direction of the electric field distribution adjusting structure, and is more effective when being located at a position within ⅓ of the thickness of the electric field distribution adjusting structure from the end in the layering direction of the electric field distribution adjusting structure.

In addition, the optical semiconductor device is configured as a semiconductor laser element in the first to third embodiments above, but the optical semiconductor device may also be configured as a semiconductor optical amplifier. In the case of being configured as a semiconductor optical amplifier, the optical semiconductor device is configured to comprise no laser resonator. In addition, in the case where the optical semiconductor device is configured as a distributed feedback (DFB) laser element, a diffraction grating layer is provided in a vicinity of the active layer.

The present disclosure has an effect of achieving an optical semiconductor device in which a decrease in manufacturing yield and an increase in manufacturing cost are reduced.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical semiconductor device comprising:
an n-type cladding layer;
a p-type cladding layer; and
an active layer interposed between the n-type cladding layer and the p-type cladding layer, wherein
the n-type cladding layer includes
a base layer, and
an electric field distribution adjusting structure configured by alternately and periodically layering multiple first layers and multiple second layers, the multiple first layers having same refractive index as the base layer, the multiple second layers having a higher refractive index than a refractive index of the first layers, and
the multiple second layers include a relaxation layer located at a position near at least one end from a center in a layering direction of the first layers and the second layers of the electric field distribution adjusting structure, the relaxation layer having a smaller thickness than a thickness of the other second layers.

2. The optical semiconductor device according to claim 1, wherein the relaxation layer has a lower refractive index than the refractive index of the other second layers.

3. The optical semiconductor device according to claim 1, wherein the multiple second layers include a first relaxation layer that is the relaxation layer located at a position near a first end from the center and a second relaxation layer that is the relaxation layer located at a position near a second end from the center.

4. The optical semiconductor device according to claim 3, wherein at least one of the first relaxation layer and the second relaxation layer has a lower refractive index than the refractive index of the other second layers.

5. The optical semiconductor device according to claim 1, wherein
the base layer and the first layers are made of InP, and
the second layer is made of a group III-V compound semiconductor including As and P as a composition.

6. An optical semiconductor device comprising:
an n-type cladding layer;
a p-type cladding layer; and
an active layer interposed between the n-type cladding layer and the p-type cladding layer, wherein
the n-type cladding layer includes
a base layer, and
an electric field distribution adjusting structure configured by alternately and periodically layering multiple first layers and multiple second layers, the multiple first layers having same refractive index as the base layer, the multiple second layers having a higher refractive index than a refractive index of the first layers,
the multiple second layers include
a first relaxation layer located at a position near a first end from a center in a layering direction of the first layers and the second layers of the electric field distribution adjusting structure, and
a second relaxation layer located at a position near a second end from the center, and
the first relaxation layer and the second relaxation layer have a lower refractive index than a refractive index of the other second layers.

7. The optical semiconductor device according to claim 6, wherein
the base layer and the first layers are made of InP, and
the second layer is made of a group III-V compound semiconductor including As and P as a composition.
